(19) United States
(12) Patent Application Publication
(10) Pub. No.: US 2026/0235681 A1
(43) Pub. Date: Aug. 13, 2026

(54) INTERNAL SHORT-CIRCUIT DETECTING METHOD AND INTERNAL SHORT-CIRCUIT DETECTING SYSTEM OF BATTERY MODULE

(71) Applicant: DELTA ELECTRONICS, INC., Taoyuan City (TW)

(72) Inventor: Yi-Lun HSU, Taoyuan City (TW)

(21) Appl. No.: 19/227,383

(22) Filed: Jun. 3, 2025

(30) Foreign Application Priority Data
Feb. 10, 2025 (CN) 202510144181.3

(51) Int. Cl. G01R 31/367; G01R 31/3842; G01R 31/52; H01M 10/44; H01M 10/46; H01M 10/48

(52) U.S. Cl. CPC G01R 31/367; G01R 31/3842; G01R 31/52; H01M 10/441; H01M 10/46; H01M 10/482

(57) ABSTRACT

An internal short-circuit detecting method includes obtaining a reference current-time data and a reference voltage-time data; obtaining a current-time data and a voltage-time data of a testing battery module; calculating a current integral quantity of the current-time data, a voltage average value of the voltage-time data, and a reference current integral quantity of the reference current-time data by a battery-cell internal short-circuit model; calculating a difference value between the current integral quantity and the reference current integral quantity to obtain an electric leakage quantity; calculating an internal short-circuit impedance value of the testing battery module; calculating a ratio value of the internal short-circuit impedance value to a square value of a value of N by a battery-cell internal short-circuit estimation model to obtain an estimated minimum internal short-circuit impedance value of one of an N quantities of battery cells of the testing battery module.

### BACKGROUND OF THE DISCLOSURE

### Technical Field

The present disclosure relates to a detecting method and a detecting system of a battery module, and especially relates to an internal short-circuit detecting method and an internal short-circuit detecting system used for a battery module.

### Description of Related Art

The internal short circuit of the battery module causes the temperature of the battery module to rise abnormally. Causes of the internal short circuit include usage aging, over-charging or over-discharging, improper arrangement or erosion/damage of the electrodes or the insulating materials of the battery module, and so on. The battery module gradually suffers from the internal short circuit, leading to the performance degradation, or even overheating which raises the safety concern. At this time, the user needs to repair or replace the battery module to avoid major dangers.

Therefore, the internal short-circuit detection for the battery module is a very important issue. Although there are currently many methods for detecting the internal short circuit, the existing internal short-circuit algorithms only estimate the power data of the battery cell and fail to estimate the internal short-circuit impedance value of the internal battery cell based on the power data of the entire battery module. Therefore, the detection results are only rough estimates. Furthermore, the current detection mechanism is limited to simple structures. Once the structural arrangement of the battery module becomes complex, the error in the estimation results also increases, failing to accurately detect the condition of the battery module.

### SUMMARY OF THE INVENTION

In order to solve the above-mentioned problems, the present disclosure provides an internal short-circuit detecting method and an internal short-circuit detecting system applied to the battery module.

According to an embodiment of the present disclosure, an internal short-circuit detecting system is provided, which includes a testing battery module, a charging control unit, an input unit, a memory unit, and a processing unit. The testing battery module includes an N quantities of battery cells (namely, the battery module includes/is composed of N battery cells), wherein a value of N is a positive integer. The charging control unit is configured to output a fixed/constant charging current to the testing battery module. The input unit is configured to receive a voltage-time data of the testing battery module measured between a charging start point and a charging end point of the testing battery module, and is configured to receive a current-time data of the testing battery module measured between the charging start point and the charging end point of the testing battery module. The memory unit is coupled to the input unit and is configured to store at least the current-time data, the voltage-time data, a reference current-time data, a reference voltage-time data, the value of N, a battery-cell internal short-circuit model, and a battery-cell internal short-circuit estimation model. The processing unit is coupled to the memory unit, and is configured to obtain the current-time data and the voltage-time data of the testing battery module, and is configured to use the current-time data and the voltage-time data to correspondingly look up the reference current-time data and the reference voltage-time data. The processing unit is configured to use the current-time data, the voltage-time data, the reference current-time data, and the reference voltage-time data to perform the battery-cell internal short-circuit model to obtain an internal short-circuit impedance value, and is configured to provide the internal short-circuit impedance value and the value of N to the battery-cell internal short-circuit estimation model to estimate an estimated minimum internal short-circuit impedance value of one of the N quantities of the battery cells in the testing battery module.

According to another embodiment of the present disclosure, an internal short-circuit detecting method is provided, which detects an estimated minimum internal short-circuit impedance value of one of an N quantities of battery cells in a testing battery module, wherein a value of N is a positive integer. The internal short-circuit detecting method includes obtaining a reference current-time data and a reference voltage-time data; obtaining a current-time data and a voltage-time data of the testing battery module; calculating a current integral quantity of the current-time data, a voltage average value of the voltage-time data, and a reference current integral quantity of the reference current-time data by a battery-cell internal short-circuit model; calculating a difference value between the current integral quantity and the reference current integral quantity to obtain an electric leakage quantity; calculating an internal short-circuit impedance value of the testing battery module; and calculating a ratio value of the internal short-circuit impedance value to a square value of the value of N by a battery-cell internal short-circuit estimation model to obtain the estimated minimum internal short-circuit impedance value of one of the N quantities of the battery cells in the testing battery module.

### BRIEF DESCRIPTION OF THE DRAWINGS

FIG. 1 shows a block diagram of the internal short-circuit detecting system according to an embodiment of the present disclosure.

FIG. 2 shows a flow chart of the internal short-circuit detecting method according to an embodiment of the present disclosure.

FIG. 3 shows a flow chart of determining the health level of the internal short circuit of the testing battery module according to an embodiment of the present disclosure.

### DETAILED DESCRIPTION

The present disclosure is further described below with reference to the drawings and the embodiments, so that relevant persons in the technical field to which the present disclosure belongs may better understand the present disclosure and implement accordingly, but the embodiments illustrated are not intended to limit the present disclosure.

Without the need to disassemble the battery module and to obtain the electrical data of each battery cell, the internal short-circuit status of the battery cell is detected by sampling the power data of the battery module and working with the operations of the algorithms to evaluate the internal short-circuit status of the entire battery module.

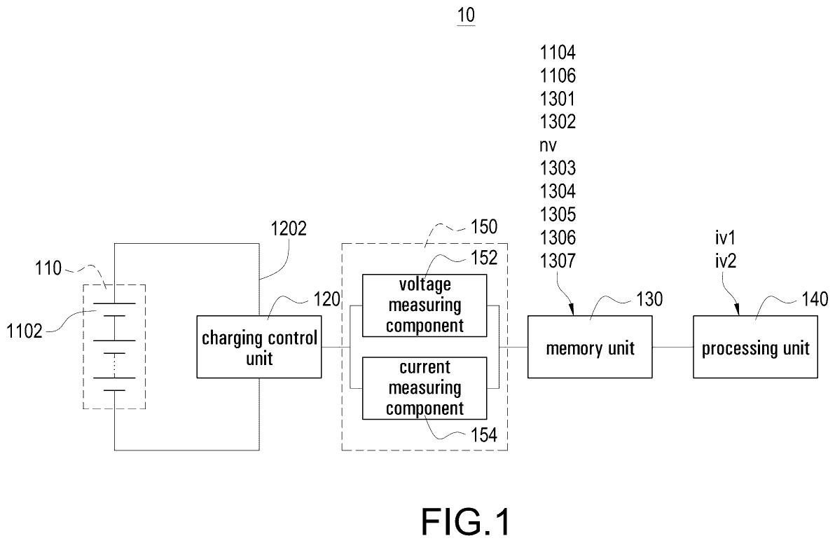

FIG. 1 shows a block diagram of the internal short-circuit detecting system 10 according to an embodiment of the present disclosure.

In an embodiment, the internal short-circuit detecting system 10 is applied to the detection for the battery module. As shown in FIG. 1, the internal short-circuit detecting system 10 includes a testing battery module 110, a charging control unit 120, a memory unit 130, a processing unit 140, and an input unit 150. The charging control unit 120 is coupled to the testing battery module 110 and the input unit 150. The memory unit 130 is coupled to the input unit 150 and the processing unit 140, and stores a plurality of program codes. The processing unit 140 performs the program codes which are stored in the memory unit 130.

The testing battery module 110 includes a plurality of battery cells 1102, such as a battery pack obtained by connecting a plurality of battery cells 1102 in series, in parallel, or in a mixed series and parallel connection.

In an embodiment, the testing battery module 110 includes a battery pack including N battery cells 1102 connected in series, wherein N is a positive integer.

The charging control unit 120 is used to output a fixed charging current 1202 to the testing battery module 110 to charge the testing battery module 110.

The input unit 150 is used to receive and measure the charging time data of the testing battery module 110 in a charging period. The charging period is the time interval between a charging start point and a charging end point.

In an embodiment, the input unit 150 includes a voltage measuring component 152 and a current measuring component 154. The voltage measuring component 152 measures a voltage-time data 1106 of the testing battery module 110 in the charging period. The current measuring component 154 measures a current-time data 1104 of the testing battery module 110 in the charging period.

The input unit 150 receives the voltage-time data 1106 of the testing battery module 110 measured between the charging start point and the charging end point, and receives the current-time data 1104 of the testing battery module 110 measured between the charging start point and the charging end point. In an embodiment, the input unit 150 receives the real-time measured voltage and the real-time measured current at each time point during the measurement time as the voltage-time-data 1106 and the current-time data 1104.

The memory unit 130 stores at least the current-time data 1104, the voltage-time data 1106, a reference current-time data 1301, a reference voltage-time data 1302, a value of N nv of an N quantities of the battery cells 1102 connected in series, a battery-cell internal short-circuit model 1303, and a battery-cell internal short-circuit estimation model 1304.

In an embodiment, the processing unit 140 of the internal short-circuit detecting system 10 creates a lookup table which includes the reference voltage-time data 1302 and the reference current-time data 1301 in advance. The reference voltage-time data 1302 and the reference current-time data 1301 are the voltage and the electric quantity (see Table 1) of a reference battery module (for example, a battery module with normal performance or no loss (for example, a qualified component that has passed factory inspection)) measured in continuous time by inputting a constant current to the reference battery module.

In an embodiment, the reference current-time data 1301 at each time point is a reference current integral quantity from the charging start point to a corresponding time point. As shown in Table 1, the reference voltage-time data 1302 at the start time 0 is 46 volts and the reference current integral quantity is 0 ampere hour. After charging for T seconds, the reference voltage-time data 1302 is 58 volts, and the reference current integral quantity is 30.75 ampere hours.

TABLE 1
the reference voltage-time data 1302 and
the reference current integral quantity

| time | voltage | electric quantity |
|---|---|---|
| (seconds) | (volts) | (ampere hour) |
| 0 | 46 | 0 |
| 1 | 46.510 | 0.00486 |
| 2 | 46.233 | 0.00972 |
| 3 | 46.333 | 0.01458 |
| . . . | . . . | . . . |
| T | 58 | 30.75 |

Compared with a battery module in a healthy internal short-circuit status, a battery module with poor internal short-circuit health consumes more charging power. Based on this, the processing unit 140 uses the quantity of the series connection of the battery cells 1102 of the testing battery module 110, and uses the current-time data 1104 and the voltage-time data 1106 measured from the testing battery module 110, and works with the reference voltage-time data 1302 and the reference current-time data 1301, to perform the battery-cell internal short-circuit model 1303 and the battery-cell internal short-circuit estimation model 1304 to estimate the estimated minimum internal short-circuit impedance value iv2 of the battery cell 1102 which is tested. Details are as follows.

In one embodiment, the processing unit 140 obtains the current-time data 1104 and the voltage-time data 1106 of the testing battery module 110, and then uses the current-time data 1104 and the voltage-time data 1106 at a certain point in time to correspondingly look up to obtain the reference current-time data 1301 and the reference voltage-time data 1302. For example, the processing unit 140 uses the voltage-time data 1106 to look up the reference voltage-time data 1302 which is the same as the voltage-time data 1106 to obtain the reference current-time data 1301 corresponding to the reference voltage-time data 1302. In one embodiment, the processing unit 140 looks up to obtain the reference current-time data 1301 and the reference voltage-time data 1302 at the charging start point and the charging end point respectively.

In one embodiment, the processing unit 140 uses the current-time data 1104, the voltage-time data 1106, the reference current-time data 1301, and the reference voltage-time data 1302 to perform the battery-cell internal short-circuit model 1303 to obtain the internal short-circuit impedance value iv1.

The description of the processing unit 140 performing the battery-cell internal short-circuit model 1303 is as follows. In one embodiment, the processing unit 140 calculates a current integral quantity of the current-time data 1104, a voltage average value of the voltage-time data 1106, and a reference current integral quantity of the reference current-time data 1301.

The processing unit 140 calculates a difference value between a start detection electric quantity at the charging start point and an end detection electric quantity at the charging end point to obtain the current integral quantity, as shown in Equation 1. Alternatively, the processing unit 140 uses a function for the current-time data 1104 to perform an integral operation on the time from the charging start point to the charging end point to obtain the current integral quantity.

$$current integral quantity = end detection electric quantity - start detection electric quantity \qquad ( Equation 1 )$$

The processing unit 140 calculates a difference value between the charging end point and the charging start point to obtain a detection time length, as shown in Equation 2.

$$detection time length = charging end point - charging start point \qquad ( Equation 2 )$$

The processing unit 140 uses the voltage-time data 1106 (namely, a start detection voltage) at the charging start point and the voltage-time data 1106 (namely, an end detection voltage) at the charging end point to perform the average operation to obtain the voltage average value.

On the other hand, the processing unit 140 uses the start detection voltage at the charging start point to correspondingly look up the reference voltage-time data 1302 which is the same as the voltage-time data 1106 to obtain a first reference current-time data and a first time value corresponding to the reference voltage-time data 1302; and, the processing unit 140 uses the end detection voltage at the charging end point to look up the reference voltage-time data 1302 which is the same as the voltage-time data 1106 to obtain a second reference current-time data and a second time value corresponding to the reference voltage-time data 1302. The processing unit 140 calculates a first reference current integral quantity from the time 0 second to the first time value, and a second reference current integral quantity from the time 0 second to the second time value.

Next, the processing unit 140 calculates a difference value between the first reference current integral quantity and the second reference current integral quantity as the reference current integral quantity (Equation 3), and calculates a difference value between the first time value and the second time value as the reference time length (Equation 4); and, the processing unit 140 calculates an electric leakage quantity between the current integral quantity and the reference current integral quantity (Equation 5) and calculates a time difference value between the detection time length and the reference time length (Equation 6).

$$reference current integral quantity = second reference current integral quantity - first reference current integral quantity \qquad ( Equation 3 )$$

$$reference time length = second time value - first time value \qquad ( Equation 4 )$$

$$electric leakage quantity = \vert current integral quantity - reference current integral quantity \vert \qquad ( Equation 5 )$$

$$time difference value = \vert detection time length - reference time length \vert \qquad ( Equation 6 )$$

For example, the charging start point of the testing battery module 110 is 0 second, the start detection voltage is 46V, the start detection electric quantity is 0 Ah, the charging end point is 1800 seconds, the end detection voltage is 58V, and the end detection electric quantity is 30.8 Ah, so the current integral quantity is 30.8 Ah, and the detection time length is 1800 seconds.

On the other hand, according to the start detection voltage, looking up Table 1 may obtain the first reference voltage which is 46V and the first reference current-time data (not shown in Table 1), and the first reference current integral quantity is calculated to be 0 Ah and the first time value is 0 second. According to the end detection voltage, looking up Table 1 may obtain the second reference voltage which is 58V and the second reference current-time data (not shown in Table 1), and the second reference current integral quantity is calculated to be 30.75 Ah and the second time value is 1600 seconds. Therefore, the reference current integral quantity (Equation 3) is 30.75V, the reference time length (Equation 4) is 1600 seconds, the electric leakage quantity (Equation 5) is 0.05 Ah, and the time difference value (Equation 6) is 200 seconds.

The processing unit 140 calculates an internal short-circuit current based on the electric leakage quantity and the time difference value. In one embodiment, the processing unit 140 calculates a ratio value of the electric leakage quantity to the time difference value to obtain the internal short-circuit current (Equation 7).

$$integral short - circuit current = \frac{electric leakage quantity}{time difference value} \qquad ( Equation 7 )$$

For example, the electric leakage quantity is 0.05 Ah and the time difference is 200 seconds, so the internal short-circuit current is 0.9 A.

Next, the processing unit 140 calculates a ratio value of the voltage average value to the internal short-circuit current to obtain the internal short-circuit impedance value iv1 of the testing battery module 110. In one embodiment, the processing unit 140 calculates the ratio value of the average value of the voltage-time data 1106 (for example, the average value of the start detection voltage and the end detection voltage) to the internal short-circuit current to obtain the internal short-circuit impedance value iv1 of the testing battery module 110 (Equation 8).

$$Internal short - circuit impedance value iv 1 = \frac{\frac{\begin{matrix}start detection voltage + \\ end detection voltage\end{matrix}}{2}}{internal short - circuit current} \qquad ( Equation 8 )$$

For example, if the voltage average value is 52V and the internal short-circuit current is 0.9 A, the internal short-circuit impedance value iv1 of the testing battery module 110 which is 57.70 is obtained through Equation 8.

In order to estimate the internal short-circuit impedance value iv2 which is the minimum among all the battery cells 1102 of the testing battery module 110, the processing unit 140 further performs the battery-cell internal short-circuit estimation model 1304, as described below.

In one embodiment, the processing unit 140 provides the internal short-circuit impedance value iv1 and the value of N nv to the battery-cell internal short-circuit estimation model 1304 to estimate the estimated minimum internal short-circuit impedance value iv2 of one of the N quantities of the battery cells 1102 of the testing battery module 110.

In one embodiment, the processing unit 140 calculates a ratio value of the internal short-circuit impedance value iv1 to a square value of the value of N nv (Equation 9) as the estimated minimum internal short-circuit impedance value iv2 of one of the N quantities of the battery cells 1102.

$$estimated minimum internal short - circuit impedance value iv 2 = \frac{internal short - circuit impedance value iv 1}{{N}^{2}} \qquad ( Equation 9 )$$

For example, if the internal short-circuit impedance value iv1 is 57.7Ω and the testing battery module 110 includes four battery cells 1102 (namely, the value of N nv is 4), the processing unit 140 calculates the estimated minimum internal short-circuit impedance value iv2 to be 3.61Ω.

It is worth mentioning that the estimated minimum internal short-circuit impedance value iv2 is the minimum estimated value of the internal short-circuit impedance value iv1 of all the battery cells 1102 of the testing battery module 110. Accordingly, the estimated minimum internal short-circuit impedance value iv2 may be used to subsequently determine the health level of the internal impedance of the testing battery module 110.

In one embodiment, the processing unit 140 checks which one of a plurality of internal short-circuit predetermined reference impedance ranges the estimated minimum internal short-circuit impedance value iv2 falls within. Each internal short-circuit predetermined reference impedance range indicates an internal short-circuit status of the battery cell 1102 to determine the level of the internal short-circuit status of the testing battery module 110.

Taking three internal short-circuit predetermined reference impedance ranges as an example, the first internal short-circuit predetermined reference impedance range 1305 is smaller than a second internal short-circuit predetermined reference impedance range 1306, and the second internal short-circuit predetermined reference impedance range 1306 is smaller than the third internal short-circuit predetermined reference impedance range 1307. For example, the first internal short-circuit predetermined reference impedance range 1305 indicates that the testing battery module 110 is severe-level internal short-circuit, the second internal short-circuit predetermined reference impedance range 1306 indicates that the testing battery module 110 is slight-level internal short-circuit, and the third internal short-circuit predetermined reference impedance range 1307 indicates that the testing battery module 110 is healthy-level internal short-circuit.

In one embodiment, the processing unit 140 relates the estimated minimum internal short-circuit impedance value iv2 to the first internal short-circuit predetermined reference impedance range 1305 to indicate that the testing battery module 110 is severe-level internal short-circuit. The processing unit 140 relates the estimated minimum internal short-circuit impedance value iv2 to the second internal short-circuit predetermined reference impedance range 1306 to indicate that the testing battery module 110 is slight-level internal short-circuit. The processing unit 140 relates the estimated minimum internal short-circuit impedance value iv2 to the third internal short-circuit predetermined reference impedance range 1307 to indicate that the testing battery module 110 is healthy-level internal short-circuit.

Since a battery-cell factor

$$\frac{1}{{N}^{2}}$$

is used in the calculation for the estimated minimum internal short-circuit impedance value iv2 (Equation 9), the calculation for the internal short-circuit impedance value iv1 is advanced from the testing battery module 110 to the battery cell 1102 which is the basic component, so that the estimated minimum internal short-circuit impedance value iv2 calculated by Equation 9 may directly show the internal impedance health status of the battery cell 1102. In this embodiment, the battery-cell factor

$$\frac{1}{{N}^{2}}$$

indicates the estimated minimum internal short-circuit impedance value iv2 of all battery cells 1102 in the testing battery module 110. For example, based on the above calculation results, the possible minimum value among the internal short-circuit impedance values iv1 of all the battery cells 1102 of the testing battery module 110 is 3.61Ω.

In addition, the smaller the impedance value, the less healthy the internal short circuit of the battery cell 1102 is. Therefore, finding the estimated minimum internal short-circuit impedance value iv2 among all battery cells 1102 helps evaluate the worst-case scenario. In the present disclosure, through the above calculation methods, the possible minimum value of the internal short-circuit impedance values iv1 of all battery cells 1102 (namely, the lower bound of the internal short-circuit impedance values iv1 which may occur in all battery cells 1102) may be obtained. Therefore, based on the battery cell 1102 as a unit, the minimum internal short-circuit impedance value iv1 may be used for evaluating the worst internal short-circuit status in the testing battery module 110. In this way, an effective and efficient method may be used to evaluate whether the testing battery module 110 should be repaired or replaced without measuring the power data of the battery cells 1102 one by one.

In one embodiment, the reference voltage-time data 1302 and the reference current-time data 1301 are measured by inputting a constant current to a battery module with normal performance or no loss, and a lookup table such as Table 1 is accordingly created based on the above description, which is not repeated here.

Since the measured values of the reference voltage-time data 1302 and the reference current-time data 1301 may be different depending on the ambient temperature, the battery module temperature, or the battery module usage stage, in another embodiment, the user may create the lookup table related to different status conditions (such as the ambient temperature, the battery module temperature, or the battery module usage stage). For example, the user may perform the above-mentioned measurements on a healthy battery module according to different ambient temperatures in advance to obtain multiple sets of voltage and the electric quantity of the reference battery module (for example, one temperature range corresponds to a lookup table). Alternatively, the user may perform the above-mentioned measurements according to different usage stages of the battery module (for example, the battery module has been used for 1 year) to obtain the voltage and the electric quantity of the reference battery module (for example, each usage stage corresponds to a lookup table). Alternatively, the user simultaneously performs the above-mentioned measurements based on the ambient temperature and the usage stage of the battery module to obtain the voltage and the electric quantity of the reference battery module. In other words, the user may create multiple lookup tables in advance, and each lookup table is suitable for different status conditions.

Before the processing unit 140 uses the start detection voltage at the charging start point to correspondingly look up the reference voltage-time data 1302 which is the same as the voltage-time data 1106, a lookup table whose status condition meets the current condition (such as the current temperature condition or the usage level of the battery module) may be selected from the multiple lookup tables. Then, the voltage-time data 1106 at the charging start point is used to look up the reference voltage-time data 1302 from the selected lookup table to obtain the first time value corresponding to the reference voltage-time data 1302, and the voltage-time data 1106 at the charging end point is used to look up the reference voltage-time data 1302 correspondingly from the selected lookup table to obtain the second time value corresponding to the reference voltage-time data 1302, as described in the relevant paragraph of the above Equation 4, which is not repeated here.

Accordingly, in the present disclosure, the multiple lookup tables related to different status conditions are created in advance. When the processing unit 140 subsequently performs the battery-cell internal short-circuit model 1303 and the battery-cell internal short-circuit estimation model 1304 to estimate the estimated minimum internal short-circuit impedance value iv2 of the battery cell 1102 which is tested, because the reference voltage-time data 1302 and the reference current-time data 1301 (which are obtained) more meet the current condition, the accuracy of the estimated minimum internal short-circuit impedance value iv2 (which is obtained) is improved to achieve more accurate estimation result.

The testing battery module 110 is, for example but not limited to, a nickel hydride battery, a nickel cadmium battery, a nickel zinc battery, a lithium ion battery, a lithium iron battery, a lead acid battery, or a combination of the above components.

The memory unit 130 is, for example but not limited to, a random access memory (RAM), a flash memory, a read only memory (ROM), a hard disk drive (HDD), a solid state drive (SSD), an optical storage, or a combination of the above components.

The processing unit 140 is, for example but not limited to, a digital signal processor (DSP), an application specific integral circuit (ASIC), a central processing unit (CPU), a system on chip (SoC), a field programmable gate array (FPGA), a network processor chip, or a combination of the above components.

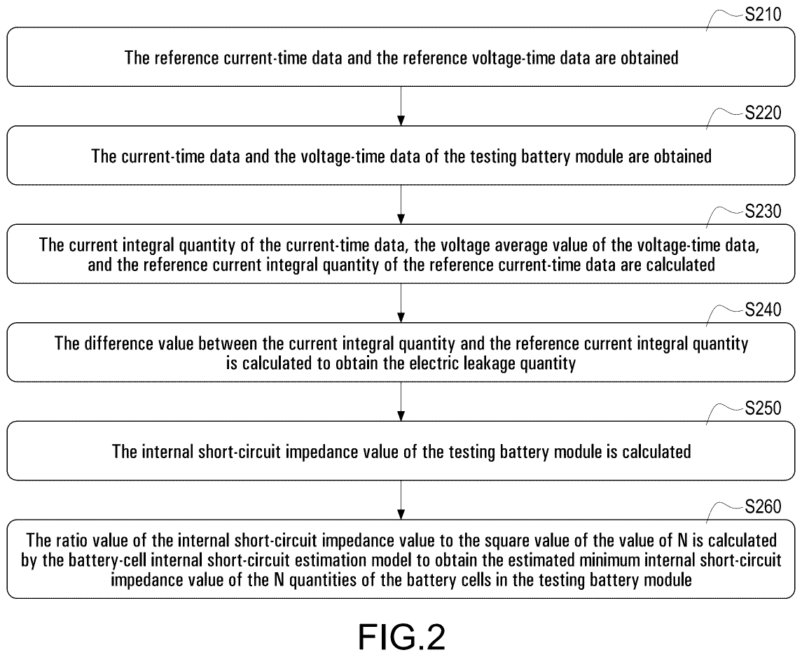

FIG. 2 shows a flow chart of the internal short-circuit detecting method according to an embodiment of the present disclosure. The internal short-circuit detecting method may be used to detect a testing battery module (such as the testing battery module 110 in FIG. 1). In an embodiment, the internal short-circuit detecting method may be performed by the internal short-circuit detecting system 10 of FIG. 1.

In the step S210, the processing unit 140 obtains the reference current-time data 1301 and the reference voltage-time data 1302 from the memory unit 130.

In one embodiment, a constant current is inputted in advance to a reference battery module (or a healthy battery module), and then the reference battery module has been charged for a period of time, and then the reference battery module is measured over continuous time to obtain the voltage and the electric quantity which are the reference voltage-time data 1302 and the reference current-time data 1301. Since a battery module with the severe internal short circuit consumes more power when being charged than a healthy battery module, the reference voltage-time data 1302 and the reference current-time data 1301 may be used as an indicator to evaluate the internal impedance of the testing battery module 110.

In the step S220, the processing unit 140 obtains the current-time data 1104 and the voltage-time data 1106 of the testing battery module 110 from the memory unit 130.

In one embodiment, the current-time data 1104 and the voltage-time data 1106 are the charging time data of the testing battery module 110 measured by the input unit 150 in the charging period. For example, the input unit 150 receives the voltage-time data 1106 of the testing battery module 110 measured from the charging start point to the charging end point, and receives the current-time data 1104 of the testing battery module 110 measured from the charging start point to the charging end point.

In the step S230, the current integral quantity of the current-time data 1104, the voltage average value of the voltage-time data 1106, and the reference current integral quantity of the reference current-time data 1301 are calculated.

In one embodiment, the step S230 calculates the difference value between the start detection electric quantity at the charging start point and the end detection electric quantity at the charging end point to obtain the current integral quantity (Equation 1) and the detection time length (Equation 2). For example, the testing battery module 110 is charged from the start detection time (for example, the 0th second), and the start detection electric quantity is 0 Ah. After a period of time, the end detection electric quantity of the testing battery module 110 at the end detection time (for example, the 1800th second) is 30.8 Ah. Therefore, the current integral quantity is 30.8 Ah and the detection time length is 1800 seconds.

In one embodiment, the step S230 uses the voltage-time data 1106 at the charging start point (namely, the start detection voltage) and the voltage-time data 1106 at the charging end point (namely, the end detection voltage) to perform the average calculation to obtain the voltage average value.

In one embodiment, the step S230 uses the start detection voltage at the charging start point to correspondingly look up the reference voltage-time data 1302 which is the same as the voltage-time data 1106 to obtain the first reference current-time data and the first time value corresponding to the reference voltage-time data 1302, and uses the end detection voltage at the charging end point to correspondingly look up the reference voltage-time data 1302 which is the same as the voltage-time data 1106 to obtain the second reference current-time data and the second time value corresponding to the reference voltage-time data 1302. Next, the step S230 calculates the first reference current integral quantity from the time 0 second to the first time value and the second reference current integral quantity from the time 0 second to the second time value, and calculates the difference value between the first reference current integral quantity and the second reference current integral quantity as the reference current integral quantity (Equation 3), and calculates the difference value between the first time value and the second time value as the reference time length (Equation 4).

For example, if the start detection voltage is 46V, the first reference voltage which is 46V, the first reference current integral quantity which is 0 Ah, and the first time value which is 0 second may be obtained by looking up Table 1 using the 46V. If the end detection voltage is 58V, the second reference current integral quantity which is 30.75 Ah and the second time value which is 1600 seconds may be obtained by looking up Table 1 using the 58V. The reference time length is the difference value between the first time value and the second time value, for example, 1600 seconds (1600 seconds-0 second).

In the step S240, the difference value between the current integral quantity and the reference current integral quantity is calculated to obtain the electric leakage quantity.

In one embodiment, the electric leakage quantity is the difference value between the current integral quantity and the reference current integral quantity (Equation 5), for example, 0.05 Ah (30.8 Ah-30.75 Ah).

In the step S250, the internal short-circuit impedance value of the testing battery module 110 is calculated.

In one embodiment, the step S250 calculates the electric leakage quantity, and calculates the time difference value between the detection time length and the reference time length, and calculates the internal short-circuit current. In one embodiment, the electric leakage quantity is the difference value between the current integral quantity and the reference current integral quantity (Equation 5), for example, 0.05 Ah (30.8 Ah-30.75 Ah). The time difference value is the difference value between the detection time length and the reference time length (Equation 6), for example, 200 seconds (1800 seconds-1600 seconds). Next, the step S250 calculates the ratio value of the electric leakage quantity to the time difference value to obtain the internal short-circuit impedance value iv1 of the testing battery module 110. For example, the internal short-circuit current of the testing battery module 110 is the ratio value of the electric leakage quantity to the time difference value (Equation 7), for example, 0.9 A (0.05 Ah/200 seconds). The internal short-circuit impedance value iv1 is the ratio value of the voltage average value to the internal short-circuit current (Equation 8), for example, 57.70 (52V/0.9 A).

It is worth mentioning that the 57.7Ω obtained at this time is the internal short-circuit impedance value iv1 of the testing battery module 110. In order to further estimate the internal short-circuit impedance value iv1 which is the minimum (hereinafter referred to as the estimated minimum internal short-circuit impedance value iv2) of all battery cells 1102 in the testing battery module 110, the battery-cell internal short-circuit estimation model 1304 is further performed in the step S260.

In the step S260, the ratio value of the internal short-circuit impedance value to the square value of the value of N is calculated to obtain the estimated minimum internal short-circuit impedance value of the N quantities of the battery cells 1102 in the testing battery module 110.

In one embodiment, the estimated minimum internal short-circuit impedance value iv2 is the internal short-circuit impedance value iv1 multiplied by the battery-cell factor

$$\frac{1}{{N}^{2}}$$

(N is the quantity of the battery cells 1102 of the testing battery module 110) (Equation 9). For example, if the value of N is 4, the estimated minimum internal short-circuit impedance value iv2 is 3.61Ω (57.7*( 1/16)).

It is worth mentioning that the above-mentioned detected voltages, detected currents, reference voltage-time data 1302, and reference current-time data 1301 are obtained by detecting the testing battery module 110 rather than a single battery cell 1102 in the testing battery module 110. However, through the calculations of the battery-cell internal short-circuit model 1303 and the battery-cell internal short-circuit estimation model 1304, the processing unit 140 may obtain the estimated minimum internal short-circuit impedance value iv2 of the battery cell 1102 which is representative in the testing battery module 110, without having to complexly disassemble the testing battery module 110 to measure the power data of the internal battery cells 1102, and may estimate the internal short-circuit health level of the entire testing battery module 110.

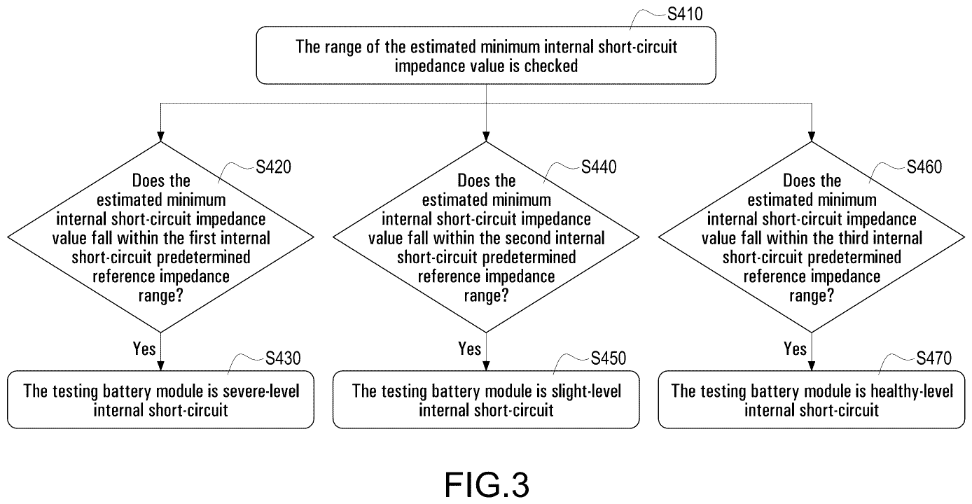

FIG. 3 shows a flow chart of determining the health level of the internal short circuit of the testing battery module 100 according to an embodiment of the present disclosure. In an embodiment, the processing unit 140 performs the step S260 in FIG. 2 to obtain the estimated minimum internal short-circuit impedance value iv2, and then determines the internal short-circuit health level of the testing battery module 110 in FIG. 3.

In the step S410, the range of the estimated minimum internal short-circuit impedance value is checked. The processing unit 140 simultaneously performs the steps S420, S440, and S460 to determine whether the estimated minimum internal short-circuit impedance value iv2 falls within the first internal short-circuit predetermined reference impedance range 1305, the second internal short-circuit predetermined reference impedance range 1306, or the third internal short-circuit predetermined reference impedance range 1307. If the estimated minimum internal short-circuit impedance value iv2 falls within the first internal short-circuit predetermined reference impedance range 1305 (the step S420), the testing battery module 110 is severe-level internal short-circuit (the step S430). If the estimated minimum internal short-circuit impedance value iv2 falls within the second internal short-circuit predetermined reference impedance range 1306 (the step S440), the testing battery module 110 is slight-level internal short-circuit (the step S450). If the estimated minimum internal short-circuit impedance value iv2 falls within the third internal short-circuit predetermined reference impedance range 1307 (the step S460), the testing battery module 110 is healthy-level internal short-circuit (the step S470). In one embodiment, the first internal short-circuit predetermined reference impedance range 1305 is smaller than the second internal short-circuit predetermined reference impedance range 1306, and the second internal short-circuit predetermined reference impedance range 1306 is smaller than the third internal short-circuit predetermined reference impedance range 1307.

In summary, the internal short-circuit detecting system 10 and the internal short-circuit detecting method provided in the present disclosure for the battery module 110 use the battery-cell internal short-circuit model 1303 to measure the voltage-time data 1106 and the current-time data 1104 of the testing battery module 110 to calculate the internal short-circuit impedance value iv1 of the testing battery module 110, and use the battery-cell internal short-circuit estimation model 1304 to make the estimation value of the internal short-circuit impedance value iv1 be advanced from the testing battery module 110 to the battery cell 1102 which is the basic component. Therefore, in the present disclosure, based on the battery cell 1102 as a unit, the worst value of the internal short-circuit level of all battery cells 1102 is estimated as the representative of the internal short-circuit level of the testing battery module 10. Accordingly, the present disclosure may calculate the estimated minimum internal short-circuit impedance value iv2 which may occur in the testing battery module 110 without the need to measure the power data of the battery cells 1102 one by one, so that the present disclosure may eliminate the trouble of disassembling the testing battery module 110 to measure the data. Accordingly, the internal short-circuit status of the testing battery module 110 may be evaluated in an effective and efficient way, allowing the user to make an early decision whether to replace the testing battery module 110 when the testing battery module 110 is slight-level internal short-circuit, thereby improving the safety of use.

The above contents are only embodiments of the present disclosure, and do not limit the patentable scope of the present disclosure. Therefore, all equivalent changes made by applying the contents of the present disclosure are similarly included in the scope of the present disclosure and are hereby stated.

What is claimed is:

1. An internal short-circuit detecting system comprising:
a testing battery module, comprising an N quantities of battery cells, wherein a value of N is a positive integer;
a charging control unit, configured to output a fixed charging current to the testing battery module;
an input unit, configured to receive a voltage-time data of the testing battery module measured between a charging start point and a charging end point, and receive a current-time data of the testing battery module measured between the charging start point and the charging end point;
a memory unit, coupled to the input unit, and configured to store at least the current-time data, the voltage-time data, a reference current-time data, a reference voltage-time data, the value of N, a battery-cell internal short-circuit model, and a battery-cell internal short-circuit estimation model; and
a processing unit, coupled to the memory unit, and configured to obtain the current-time data and the voltage-time data of the testing battery module, and use the current-time data and the voltage-time data to correspondingly look up the reference current-time data and the reference voltage-time data,
wherein the processing unit is configured to use the current-time data, the voltage-time data, the reference current-time data, and the reference voltage-time data to perform the battery-cell internal short-circuit model to obtain an internal short-circuit impedance value, and provide the internal short-circuit impedance value and the value of N to the battery-cell internal short-circuit estimation model to estimate an estimated minimum internal short-circuit impedance value of one of the N quantities of the battery cells in the testing battery module.

2. The internal short-circuit detecting system of the claim 1, wherein the memory unit is configured to store a first internal short-circuit predetermined reference impedance range, a second internal short-circuit predetermined reference impedance range, and a third internal short-circuit predetermined reference impedance range; the processing unit is configured to relate the estimated minimum internal short-circuit impedance value to the first internal short-circuit predetermined reference impedance range to indicate that the testing battery module is severe-level internal short-circuit, relate the estimated minimum internal short-circuit impedance value to the second internal short-circuit predetermined reference impedance range to indicate that the testing battery module is slight-level internal short-circuit, and relate the estimated minimum internal short-circuit impedance value to the third internal short-circuit predetermined reference impedance range to indicate that the testing battery module is healthy-level internal short-circuit.

3. The internal short-circuit detecting system of the claim 1, wherein the testing battery module comprises the N quantities of the battery cells connected in series.

4. The internal short-circuit detecting system of the claim 1, wherein operation of the processing unit performing the battery-cell internal short-circuit model to obtain the internal short-circuit impedance value comprises:
calculating a current integral quantity of the current-time data, a voltage average value of the voltage-time data, and a reference current integral quantity of the reference current-time data;
calculating a difference value between the current integral quantity and the reference current integral quantity to obtain an electric leakage quantity;
calculating a ratio value of the electric leakage quantity to a time difference value corresponding to the reference current integral quantity to obtain an internal short-circuit current; and
calculating a ratio value of the voltage average value to the internal short-circuit current to obtain the internal short-circuit impedance value of the testing battery module.

5. The internal short-circuit detecting system of the claim 4, wherein operation of the processing unit calculating the reference current integral quantity of the reference current-time data comprises:
using the voltage-time data at the charging start point to correspondingly look up the reference voltage-time data to obtain a first reference current integral quantity corresponding to the reference voltage-time data;
using the voltage-time data at the charging end point to correspondingly look up the reference voltage-time data to obtain a second reference current integral quantity corresponding to the reference voltage-time data; and
calculating a difference value between the first reference current integral quantity and the second reference current integral quantity as the reference current integral quantity.

6. The internal short-circuit detecting system of the claim 4, wherein operation of the processing unit calculating the time difference value corresponding to the reference current integral quantity comprises:
using the voltage-time data at the charging start point to correspondingly look up the reference voltage-time data to obtain a first time value corresponding to the reference voltage-time data;
using the voltage-time data at the charging end point to correspondingly look up the reference voltage-time data to obtain a second time value corresponding to the reference voltage-time data;
calculating a difference value between the first time value and the second time value to obtain a reference time length, and calculating a difference value from the charging start point to the charging end point to obtain a detection time length; and
calculating a difference value between the detection time length and the reference time length to obtain the time difference value.

7. The internal short-circuit detecting system of the claim 6, wherein the processing unit is configured to create a plurality of lookup tables comprising the reference current-time data and the reference voltage-time data in advance; each of the lookup tables is related to a status condition; the processing unit is configured to select one of the lookup tables based on the status condition meeting a current condition, use the voltage-time data at the charging start point to look up the reference voltage-time data from the lookup table being selected to obtain the first time value corresponding to the reference voltage-time data, and use the voltage-time-data at the charging end point to correspondingly look up the reference voltage-time data from the lookup table being selected to obtain the second time value corresponding to the reference voltage-time data;
wherein the status condition is at least one of an ambient temperature, a temperature of the testing battery module, and a usage stage of the testing battery module.

8. The internal short-circuit detecting system of the claim 1, wherein operation of the processing unit performing the battery-cell internal short-circuit estimation model to obtain the estimated minimum internal short-circuit impedance value comprises:
calculating a ratio value of the internal short-circuit impedance value to a square value of the value of N as the estimated minimum internal short-circuit impedance value of one of the N quantities of the battery cells.

9. An internal short-circuit detecting method, used to detect an estimated minimum internal short-circuit impedance value of one of an N quantities of battery cells in a testing battery module, a value of N being a positive integer, the internal short-circuit detecting method comprising:
obtaining a reference current-time data and a reference voltage-time data;
obtaining a current-time data and a voltage-time data of the testing battery module;
calculating a current integral quantity of the current-time data, a voltage average value of the voltage-time data, and a reference current integral quantity of the reference current-time data by a battery-cell internal short-circuit model;
calculating a difference value between the current integral quantity and the reference current integral quantity to obtain an electric leakage quantity;
calculating an internal short-circuit impedance value of the testing battery module; and
calculating a ratio value of the internal short-circuit impedance value to a square value of the value of N by a battery-cell internal short-circuit estimation model to obtain the estimated minimum internal short-circuit impedance value of one of the N quantities of the battery cells in the testing battery module.

10. The internal short-circuit detecting method of the claim 9, after obtaining the estimated minimum internal short-circuit impedance value, further comprising:
relating the estimated minimum internal short-circuit impedance value to a first internal short-circuit predetermined reference impedance range to indicate that the testing battery module is severe-level internal short-circuit;
relating the estimated minimum internal short-circuit impedance value to a second internal short-circuit predetermined reference impedance range to indicate that the testing battery module is slight-level internal short-circuit; and
relating the estimated minimum internal short-circuit impedance value to a third internal short-circuit predetermined reference impedance range to indicate that the testing battery module is healthy-level internal short-circuit.

11. The internal short-circuit detecting method of the claim 9, wherein the testing battery module comprises the N quantities of the battery cells connected in series.

12. The internal short-circuit detecting method of the claim 9, wherein calculating the reference current integral quantity of the reference current-time data comprises:
using the voltage-time data at a charging start point to correspondingly look up the reference voltage-time data to obtain a first reference current integral quantity corresponding to the reference voltage-time data;
using a voltage of the current-time data at a charging end point to correspondingly look up the reference voltage-time data to obtain a second reference current integral quantity corresponding to the reference voltage-time data; and
calculating a difference value between the first reference current integral quantity and the second reference current integral quantity as the reference current integral quantity.

13. The internal short-circuit detecting method of the claim 9, wherein calculating the internal short-circuit impedance value of the testing battery module comprises:
calculating a ratio value of the electric leakage quantity to a time difference value corresponding to the reference current integral quantity to obtain an internal short-circuit current; and
calculating a ratio value of the voltage average value to the internal short-circuit current to obtain the internal short-circuit impedance value of the testing battery module.

14. The internal short-circuit detecting method of the claim 12, wherein calculating the time difference value corresponding to the reference current integral quantity comprises:
using the voltage-time data at the charging start point to correspondingly look up the reference voltage-time data to obtain a first time value corresponding to the reference voltage-time data;
using the voltage-time data at the charging end point to correspondingly look up the reference voltage-time data to obtain a second time value corresponding to the reference voltage-time data;
calculating a difference value between the first time value and the second time value to obtain a reference time length, and calculating a difference value from the charging start point to the charging end point to obtain a detection time length; and
calculating a difference value between the detection time length and the reference time length to obtain the time difference value.

15. The internal short-circuit detecting method of the claim 14, further comprising:
creating a plurality of lookup tables comprising the reference current-time data and the reference voltage-time data in advance, wherein each of the lookup tables is related to a status condition,
wherein calculating the time difference value corresponding to the reference current integral quantity further comprises:
selecting one of the lookup tables based on the status condition meeting a current condition;
using the voltage-time data at the charging start point to look up the reference voltage-time data from the lookup table being selected to obtain the first time value corresponding to the reference voltage-time data; and
using the voltage-time-data at the charging end point to correspondingly look up the reference voltage-time data from the lookup table being selected to obtain the second time value corresponding to the reference voltage-time data,
wherein the status condition is at least one of an ambient temperature, a temperature of the testing battery module, and a usage stage of the testing battery module.

16. The internal short-circuit detecting method of the claim 9, wherein obtaining the current-time data and the voltage-time data of the testing battery module comprises:
obtaining the voltage-time data of the testing battery module measured between a charging start point and a charging end point, and obtaining the current-time data of the testing battery module measured between the charging start point and the charging end point.

17. The internal short-circuit detecting method of the claim 15, wherein calculating the current integral quantity of the current-time data and the voltage average value of the voltage-time data comprises:
calculating the current-time data and performing an integral operation from the charging start point to the charging end point in time to obtain the current integral quantity; and
using the voltage-time data at the charging start point and the voltage-time data at the charging end point to perform an average calculation to obtain the voltage average value.
